(19) United States
(12) Patent Application Publication
(10) Pub. No.: US 2026/0357417 A1
(43) Pub. Date: Nov. 12, 2026

(54) FABRICATION BY SELF-ASSEMBLY

(71) Applicant: International Business Machines Corporation, Armonk, NY (US)

(72) Inventor: Damon Brooks Farmer, White Plains, NY (US)

(21) Appl. No.: 18/599,496

(22) Filed: Mar. 8, 2024

(51) Int. Cl. C23C 16/04; C23C 16/34; C23C 16/455; C23C 16/56

(52) U.S. Cl. CPC C23C 16/045; C23C 16/34; C23C 16/45555; C23C 16/56

(57) ABSTRACT

A method of fabrication by self-assembly is provided. The method includes preparing a substrate, patterning a deposition template onto the substrate to define a gap, functionalizing substrate surfaces to be inactive to an atomic layer deposition (ALD) process and deposition template surfaces to be active to the ALD process, area-selective ALD processing whereby deposited material does not nucleate and grow on the substrate surfaces and does nucleate and grow on the deposition template surfaces such that the gap is reformed as a reformed gap between deposition material surfaces and continuing the area-selective ALD processing whereby the reformed gap narrows without closing.

### BACKGROUND

The present disclosure generally relates to fabrication methods and resulting structures for devices. More specifically, the present disclosure relates fabrication by self-assembly.

Nano-electrochemistry is a branch of electrochemistry that investigates the electrical and electrochemical properties of materials at the nanometer size regime. Nano-electrochemistry plays significant role in the fabrication of various sensors and devices for accomplishing tasks at very small size ranges and/or at very low concentrations.

Nano-electrochemistry can be employed to form nanoelectrodes. Nanoelectrodes are tiny electrodes made of metals or semiconducting materials having typical dimensions of 1-100 nm. Various forms of nanoelectrodes have been developed taking advantage of the different possible fabrication techniques.

### SUMMARY

According to an aspect of the disclosure, a method of fabrication by self-assembly is provided. The method includes preparing a substrate, patterning a deposition template onto the substrate to define a gap, functionalizing substrate surfaces to be inactive to an atomic layer deposition (ALD) process and deposition template surfaces to be active to the ALD process, area-selective ALD processing whereby deposited material does not nucleate and grow on the substrate surfaces and does nucleate and grow on the deposition template surfaces such that the gap is reformed as a reformed gap between deposition material surfaces and continuing the area-selective ALD processing whereby the reformed gap narrows without closing. In additional or alternative embodiments, the area-selective ALD processes selectively deposit materials on predefined regions that subsequently laterally encroach towards each other during the ALD processes.

According to an aspect of the disclosure, a method of fabrication by self-assembly is provided. The method includes preparing a substrate including substrate surfaces, patterning a deposition template onto the substrate to include deposition template surfaces and to define a gap between opposing ones of the deposition template surfaces, functionalizing the substrate surfaces to be inactive to an atomic layer deposition (ALD) process and the deposition template surfaces to be active to the ALD process, area-selective ALD processing whereby deposited material does not nucleate and grow on the substrate surfaces and does nucleate and grow on the deposition template surfaces such that the gap is reformed as a reformed gap between opposing deposition material surfaces corresponding to the opposing ones of the deposition template surfaces and continuing the area-selective ALD processing whereby the reformed gap narrows without closing. In additional or alternative embodiments, the area-selective ALD processes selectively deposit materials on predefined regions that subsequently laterally encroach towards each other during the ALD processes.

According to an aspect of the disclosure, a self-assembled device is provided and includes a substrate including substrate surfaces functionalized to be inactive to atomic layer deposition (ALD), a deposition template patterned onto the substrate and including deposition template surfaces functionalized to be active to the ALD and defining a gap between opposing ones of the deposition template surfaces, area-selective ALD deposited material, which is nucleated and grown on the deposition template surfaces such that the gap is reformed as a reformed gap between opposing deposition material surfaces corresponding to the opposing ones of the deposition template surfaces. In additional or alternative embodiments, the area-selective ALD deposited materials laterally encroach towards each other during the ALD processes.

Additional technical features and benefits are realized through the techniques of the present disclosure. Embodiments and aspects of the disclosure are described in detail herein and are considered a part of the claimed subject matter. For a better understanding, refer to the detailed description and to the drawings.

### BRIEF DESCRIPTION OF THE DRAWINGS

The specifics of the exclusive rights described herein are particularly pointed out and distinctly claimed in the claims at the conclusion of the specification. The foregoing and other features and advantages of the embodiments of the disclosure are apparent from the following detailed description taken in conjunction with the accompanying drawings in which:

FIG. 1 is a flow diagram illustrating a method of fabrication by self-assembly in accordance with one or more embodiments;

FIG. 2 is a top-down view of an initial device structure in accordance with one or more embodiments;

FIG. 3 is a top-down view of a device structure in accordance with one or more embodiments;

FIG. 4A is a side view of the device structure of FIG. 3 taken along line 4-4 in accordance with one or more embodiments;

FIG. 4B is an enlarged image of the side view of FIG. 4A in accordance with one or more embodiments;

FIG. 5 is a graphical illustration of resistance of shorted and non-shorted devices in accordance with one or more embodiments;

FIG. 6A is a flow diagram illustrating further operations of the method of fabrication by self-assembly of FIG. 1 in accordance with one or more embodiments;

FIG. 6B is a graphical illustration of small-field junction resistance versus increasing annealing temperatures in accordance with one or more embodiments;

FIG. 7 is a diagram illustrating oxidation and selective etching operations of FIG. 6 in accordance with one or more embodiments; and

FIG. 8 is a flow diagram illustrating a method of forming conductors by self-assembly in accordance with one or more embodiments.

The diagrams depicted herein are illustrative. There can be many variations to the diagram or the operations described therein without departing from the spirit of the disclosure. For instance, the actions can be performed in a differing order or actions can be added, deleted or modified. Also, the term “coupled” and variations thereof describes having a communications path between two elements and does not imply a direct connection between the elements with no intervening elements/connections between them. All of these variations are considered a part of the specification.

In the accompanying figures and following detailed description of the described embodiments, the various elements illustrated in the figures are provided with two or three digit reference numbers. With minor exceptions, the leftmost digit(s) of each reference number correspond to the figure in which its element is first illustrated.

### DETAILED DESCRIPTION

According to an aspect of the disclosure, a method of fabrication by self-assembly is provided. The method includes preparing a substrate, patterning a deposition template onto the substrate to define a gap, functionalizing substrate surfaces to be inactive to an atomic layer deposition (ALD) process and deposition template surfaces to be active to the ALD process, area-selective ALD processing whereby deposited material does not nucleate and grow on the substrate surfaces and does nucleate and grow on the deposition template surfaces such that the gap is reformed as a reformed gap between deposition material surfaces and continuing the area-selective ALD processing whereby the reformed gap narrows without closing. In additional or alternative embodiments, the area-selective ALD processes selectively deposit materials on predefined regions that subsequently laterally encroach towards each other during the ALD processes.

In accordance with additional or alternative embodiments, an initial size of the gap is about 20 nm to about 65 nm and a final size of the reformed gap is on a sub-nanometer scale. The reformed gap enables or promotes quantum tunneling.

In accordance with additional or alternative embodiments, at least one of the substrate includes dielectric material, the deposition template includes metallic material and the deposited material includes a metallic nitride. Each material is readily available.

In accordance with additional or alternative embodiments, the functionalizing of the substrate surfaces includes surface hydrogen removal and replacement with materials that prohibit ALD precursors from nucleating so that the substrate surface is ALD-inactive.

In accordance with additional or alternative embodiments, the substrate includes silicon dioxide, the deposition template includes aluminum, the deposited material include titanium nitride and the functionalizing of the substrate surfaces and the deposition template surfaces includes exposure to nitrogen trifluoride plasma. Each material is readily available and the functionalizing makes the substrate surfaces ALD-inactive and the deposition template surfaces ALD-active.

In accordance with additional or alternative embodiments, the method further includes annealing the deposition material surfaces at least at the reformed gap in air for further processing.

In accordance with additional or alternative embodiments, the method further includes oxidizing the deposition material surfaces at least at the reformed gap to form modified layers and selectively etching the modified layers to enlarge the reformed gap to a predefined width so that the gaps can provide for a certain resistance or for a base for additional deposition.

According to an aspect of the disclosure, a method of fabrication by self-assembly is provided. The method includes preparing a substrate including substrate surfaces, patterning a deposition template onto the substrate to include deposition template surfaces and to define a gap between opposing ones of the deposition template surfaces, functionalizing the substrate surfaces to be inactive to an atomic layer deposition (ALD) process and the deposition template surfaces to be active to the ALD process, area-selective ALD processing whereby deposited material does not nucleate and grow on the substrate surfaces and does nucleate and grow on the deposition template surfaces such that the gap is reformed as a reformed gap between opposing deposition material surfaces corresponding to the opposing ones of the deposition template surfaces and continuing the area-selective ALD processing whereby the reformed gap narrows without closing. In additional or alternative embodiments, the area-selective ALD processes selectively deposit materials on predefined regions that subsequently laterally encroach towards each other during the ALD processes.

In accordance with additional or alternative embodiments, an initial size of the gap between the opposing ones of the deposition template surfaces is about 20 nm to about 65 nm and a final size of the reformed gap between the opposing deposition material surfaces is on a sub-nanometer scale. The reformed gap enables or promotes quantum tunneling.

In accordance with additional or alternative embodiments, at least one of the substrate includes dielectric material, the deposition template includes metallic material and the deposited material includes a metallic nitride. Each material is readily available.

In accordance with additional or alternative embodiments, the functionalizing of the substrate surfaces includes surface hydrogen removal and replacement with materials that prohibit ALD precursors from nucleating so that the substrate surface is ALD-inactive.

In accordance with additional or alternative embodiments, the substrate includes silicon dioxide, the deposition template includes aluminum, the deposited material includes titanium nitride and the functionalizing of the substrate surfaces and the deposition template surfaces includes exposure to nitrogen trifluoride plasma. Each material is readily available and the functionalizing makes the substrate surfaces ALD-inactive and the deposition template surfaces ALD-active.

In accordance with additional or alternative embodiments, the method further includes annealing the deposition material surfaces at least at the reformed gap between the opposing deposition material surfaces in air for further processing.

In accordance with additional or alternative embodiments, the method further includes oxidizing the deposition material surfaces at least at the reformed gap between the opposing deposition material surfaces to form modified layers and selectively etching the modified layers to enlarge the reformed gap between the opposing deposition material surfaces to a predefined width so that the gaps can provide for a certain resistance or for a base for additional deposition.

According to an aspect of the disclosure, a self-assembled device is provided and includes a substrate including substrate surfaces functionalized to be inactive to atomic layer deposition (ALD), a deposition template patterned onto the substrate and including deposition template surfaces functionalized to be active to the ALD and defining a gap between opposing ones of the deposition template surfaces, area-selective ALD deposited material, which is nucleated and grown on the deposition template surfaces such that the gap is reformed as a reformed gap between opposing deposition material surfaces corresponding to the opposing ones of the deposition template surfaces. In additional or alternative embodiments, the area-selective ALD deposited materials laterally encroach towards each other during the ALD processes.

In accordance with additional or alternative embodiments, an initial size of the gap between the opposing ones of the deposition template surfaces is about 20 nm to about 65 nm and a final size of the reformed gap between the opposing deposition material surfaces is on a sub-nanometer scale and the opposing depositional material surfaces are rounded. The reformed gap enables or promotes quantum tunneling.

In accordance with additional or alternative embodiments, a thickness of the deposition template is about 1 nm but could be much smaller or larger than that.

In accordance with additional or alternative embodiments, at least one of the substrate includes dielectric material, the deposition template includes metallic material and the area-selective ALD deposited material includes a metallic nitride. Each material is readily available.

In accordance with additional or alternative embodiments, the substrate includes silicon dioxide, the deposition template includes aluminum, the deposited material includes titanium nitride and the substrate surfaces and the deposition template surfaces are functionalized by exposure to nitrogen trifluoride plasma. Each material is readily available and the functionalizing makes the substrate surfaces ALD-inactive and the deposition template surfaces ALD-active.

In accordance with additional or alternative embodiments, a non-dimensional electrical resistance across the reformed gap between the opposing deposition material surfaces is about 1 or less than 1 for all temperatures, T, where 300K<T<at least 400 which is evidence of there being a gap.

For the sake of brevity, conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

Turning now to an overview of technologies that are more specifically relevant to aspects of the disclosure, it is very difficult to fabricate physical gaps between structures that are several nanometers to sub-nanometer in width without the requirement of multi-level lithography, multi-step metal deposition processes, the intentional insertion of a spacer material or the need to rotate or tilt the sample substrate in order to define the material placement. These issues are particularly noticeable when materials that are compatible with front-end-of-line (FEOL) and back-end-of-line (BEOL) complementary-metal-oxide-semiconductor (CMOS) processes are used.

Work in the field of fabricating physical gaps between structures that are several nanometers to sub-nanometer in width has been proposed. The proposals generally employ complicated, multi-step lithography, deposition and etching schemes to facilitate gap fabrication. The proposals also tend to use material sets that may not be compatible for certain CMOS applications.

Turning now to an overview of the aspects of the disclosure, one or more embodiments of the disclosure address the above-described shortcomings of the prior art by providing area-selective atomic layer deposition (ALD) processes to selectively deposit materials on predefined regions that subsequently laterally encroach towards each other during the ALD processes. During the ALD processes, the spacing between structures decreases and is eventually self-limited to several nanometers to sub-nanometer gap distances. In particular, this allows for wafer-scale nanogap fabrication without the requirement of multi-level lithography, multi-step metal deposition processes, intentional insertion of a spacer material or the need to rotate or tilt the sample substrate in order to define the material placement. Material sets that are both FEOL and BEOL compatible can be used. The process flow is uncomplicated.

The above-described aspects of the disclosure address the shortcomings of the prior art by providing for a method of fabrication by self-assembly. The method includes preparing a substrate, patterning a deposition template onto the substrate to define a gap, functionalizing substrate surfaces to be inactive to an atomic layer deposition (ALD) process and deposition template surfaces to be active to the ALD process, ALD processing whereby deposited material does not nucleate and grow on the substrate surfaces and does nucleate and grow on the deposition template surfaces such that the gap is reformed as a reformed gap between deposition material surfaces and continuing the ALD processing whereby the reformed gap narrows without closing.

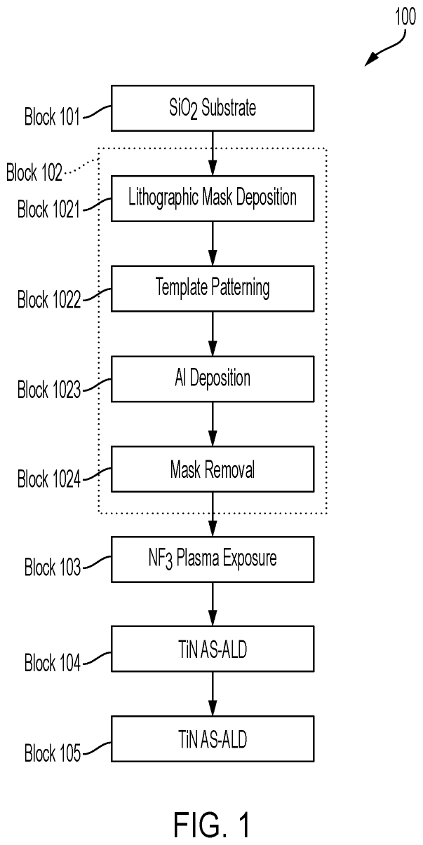

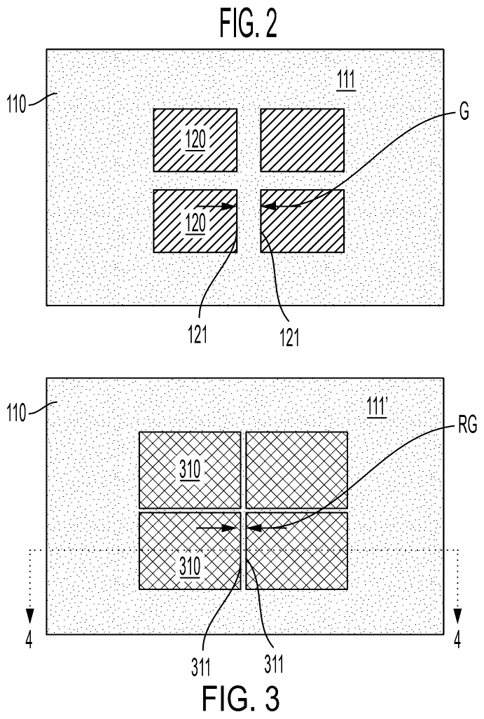

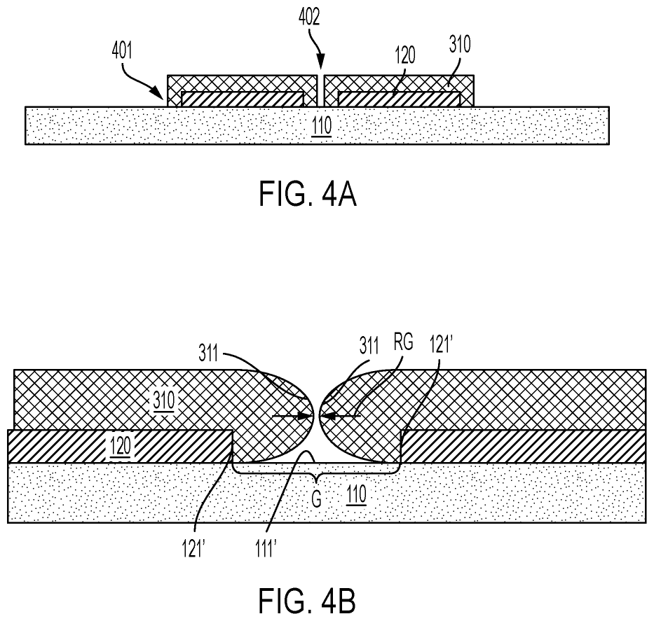

Turning now to a more detailed description of aspects of the present disclosure, FIG. 1 depicts a method 100 of fabrication by self-assembly, FIG. 2 is a top-down view of an initial device structure, FIG. 3 is a top-down view of a device structure and FIGS. 4A and 4B are side (regular and enlarged) views of the device structure of FIG. 3.

At block 101, the method 100 includes initially preparing a substrate 110 including substrate surfaces 111 (see FIG. 2). At block 102, the method 100 includes patterning a deposition template 120 (see FIG. 2) onto the substrate 110. The patterning of block 102 can include a lithographic mask deposition at block 1021, template patterning at block 1022, deposition of material of the deposition template at block 1023 and mask removal at block 1024. As a result of the patterning of the deposition template 120, the deposition template 120 includes deposition template surfaces 121 (see FIG. 2) and is formed to define a gap G between opposing ones of the deposition template surfaces 121.

At block 103, the method 100 further includes functionalizing the substrate surfaces 111 of FIG. 2 to be post-functionalized substrate surfaces 111′ that are inactive to an ALD process and functionalizing the deposition template surfaces 121 of FIG. 2 to be post-functionalized deposition template surfaces 121′ (see FIGS. 4A and 4B) that are active to the ALD process. Next, at block 104, area-selective ALD processing is executed whereby area-selective ALD deposited material 310 (see FIGS. 3, 4A and 4B) does not nucleate and grow on the post-functionalized substrate surfaces 111′ and does nucleate and grow in all available directions on the post-functionalized deposition template surfaces 121′. The area-selective ALD deposited material 310 thus includes deposition material surfaces 311 such that the gap G of FIG. 2 is effectively reformed as a reformed gap RG (see FIG. 3) between opposing ones of the deposition material surfaces 311 that respectively correspond to the opposing ones of the deposition template surfaces 121. At block 105, the area-selective ALD processing continues whereby the reformed gap RG narrows without closing as shown in FIGS. 3A and 3B.

In accordance with one or more embodiments, at least an initial size of the gap G between the opposing ones of the deposition template surfaces 121 of FIG. 2 can be about 20 nm to about 65 nm whereas a final size of the reformed gap RG between the opposing ones of the deposition material surfaces 311 of FIGS. 3, 4A and 4B is on a sub-nanometer scale (several nanometers to sub-nanometer scales or less).

As the area-selective ALD processing continues, the reformed gap RG between the opposing ones of the deposition material surfaces 311 decreases. Eventually, the reformed gap RG decreases to a length that is several nanometers to sub-nanometer scale in dimensions without completely closing up due to the self-limiting growth of the area-selective ALD deposited material 310. At a conclusion of the area-selective ALD processing of blocks 104 and 105 of FIG. 1, a cross-sectional area of the area-selective ALD deposited material 310 on either side of the reformed gap RG can be proportional to an amount of the area-selective ALD deposited material 310 that was deposited.

In accordance with embodiments, at least one of the substrate 110 can include dielectric material, the deposition template 120 can include metallic material and the area-selective ALD deposited material 310 can include a metallic nitride or another conductor. In these or other cases, the functionalizing of the substrate surfaces 111 can include processes of surface hydrogen removal and replacement with materials, such as a fluorine, that prohibit ALD precursors from nucleating. In accordance with one or more further embodiments, the substrate 110 can include silicon dioxide, the deposition template 120 can include aluminum and the area-selective ALD deposited material 310 can include titanium nitride. In these or other cases, the functionalizing of the substrate surfaces 111 and the deposition template surfaces 121 can include exposure of the substrate surfaces 111 and the deposition template surfaces 121 to nitrogen trifluoride plasma.

As shown in FIGS. 4A and 4B, a self-assembled device 401 is provided with, for example, a self-assembled tunnel junction 402 or another type of junction. The self-assembled device 401 includes the substrate 110, the deposition template 120 and the area-selective ALD deposited material 310. The substrate 110 includes the post-functionalized substrate surfaces 111′ that are functionalized to be inactive to ALD processing. The deposition template 120 is patterned onto the substrate 110 and has a thickness of about one atomic monolayer to hundreds of nanometers (e.g., 1 nm). The deposition template 120 includes the post-functionalized deposition template surfaces 121′ that are functionalized to be active to the ALD processing. The deposition template 120 is formed to define the gap G between opposing ones of the post-functionalized deposition template surfaces 121′ with at least an initial size of about 5 nm to hundreds of nanometers or, in some cases, about 20 nm to about 65 nm (given a high-quality selectivity of the ASD processing, ALD material will not nucleate on the ALD-inactive surface; with enough ALD cycles, material deposited on the ALD-active areas will eventually come together to form a gap, regardless of an initial spacing). The area-selective ALD deposited material 310 is prohibited from being nucleated and grown on the post-functionalized substrate surfaces 111′ and is nucleated and grown on the post-functionalized deposition template surfaces 121′. The area-selective ALD deposited material 310 includes the deposition material surfaces 311, which can be rounded. As such, the gap G is effectively reformed as the reformed gap RG between opposing ones of the deposition material surfaces 311 corresponding to the opposing ones of the post-functionalized deposition template surfaces 121′. A final size of the reformed gap RG between the opposing ones of the deposition material surfaces 311 can be several nanometers to sub-nanometer scales.

In some cases, the reformed gap RG between the opposing ones of the deposition material surfaces 311 can be small enough to enable or promote quantum tunneling effects between the opposing ones of the deposition material surfaces 311.

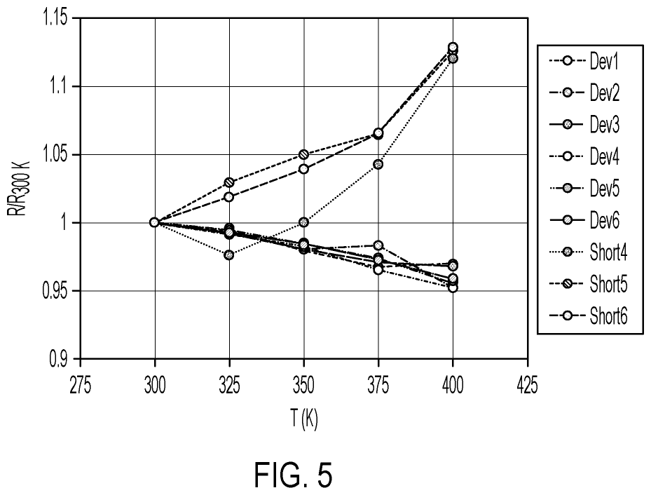

With continued reference to FIG. 4B and with additional reference to FIG. 5, a normalized electrical resistance across the reformed gap RG between the opposing ones of the deposition material surfaces 311 can be about 1 or less than 1 for all temperatures, T, where 300K<T<at least 400 K. As shown in FIG. 5, shorted devices and devices with a gap (i.e., the gap G/the reformed gap RG) were measured at five different temperatures: 300 K, 325 K, 350 K, 375 K, and 400 K. I-V (+/−100 mV, linear regime) measurements were made, and the resistances were extrapolated based on the linear I-V response. Resistance increases with increasing T for the shorted devices, which accords with thermal responses of metals due to phonon scattering. For the devices with the gaps, resistance decreases with increasing T, indicating the presence of thermionic carrier excitation over the barrier formed by the gap.

It is to be understood that, while the gap G and the reformed gap RG are illustrated in FIGS. 2 and 3, other embodiments are possible. For example, in an exemplary case, in which it is desired that the reformed gap RG be curved, the deposition template 120 can be patterned such that the gap G is curved. The present description will, however, relate to the case in which the gap G and the reformed gap RG are linear. This is being done for purposes of clarity and brevity and should not be interpreted as limiting the description or the following claims in any way.

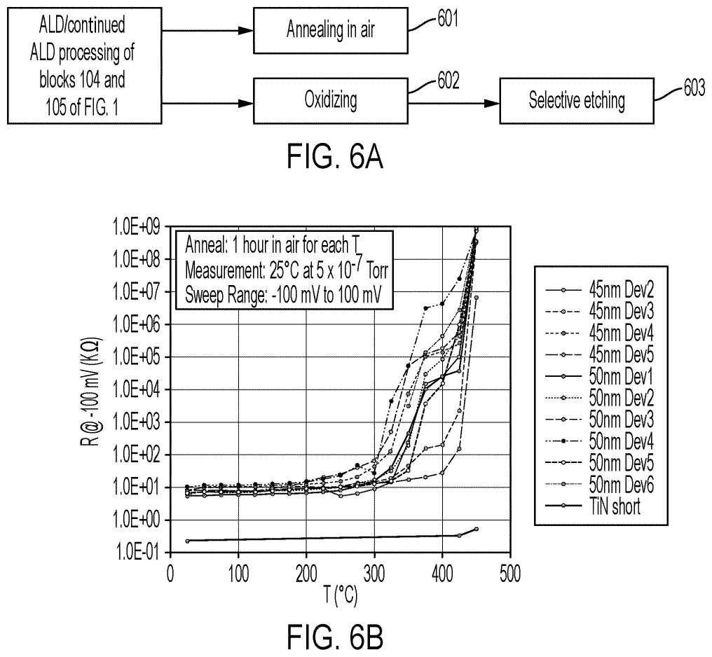

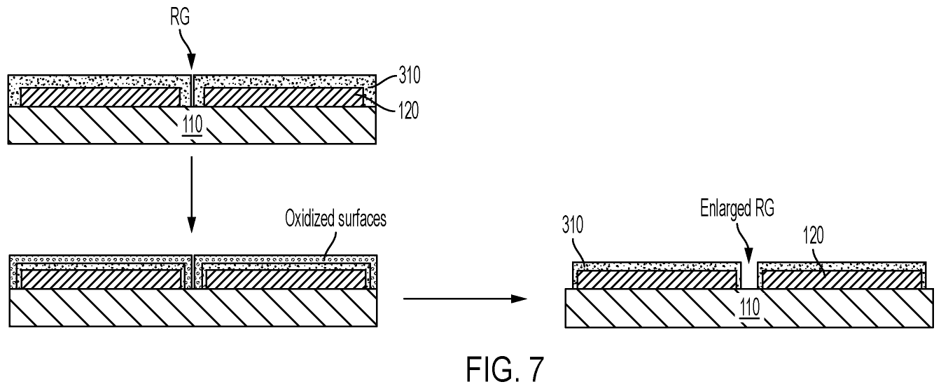

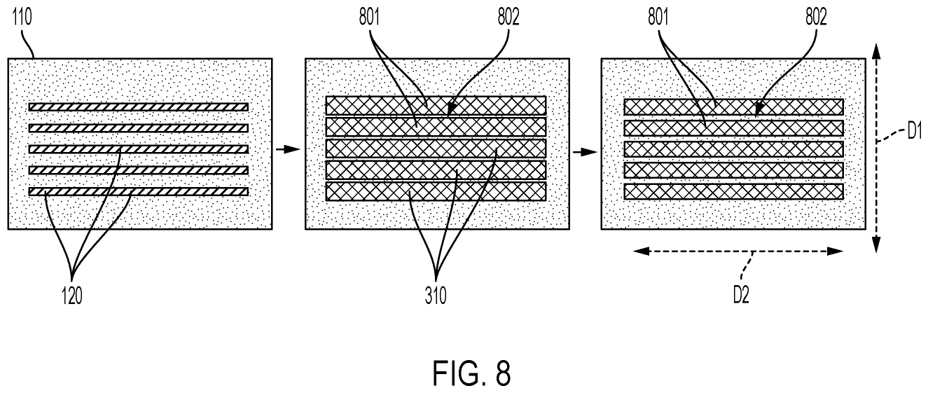

With reference back to FIG. 1 and with additional reference to FIGS. 6A, 6B and to FIGS. 7 and 8, following the area-selective ALD and the continuation of the area-selective ALD of blocks 104 and 105 of FIG. 1, the deposition material surfaces 311 (see FIGS. 3 and 4B) can be annealed in air at least at the reformed gap RG (block 601) and/or oxidized to form modified layers (block 602) with the modified layers being selectively etched to enlarge the reformed gap RG to a predefined size or width (block 603) at least at the reformed gap RG.

The annealing of block 601 can be used to determine whether a tunnel barrier thickness (i.e., a size of the reformed gap RG) can be increased via oxidation which could change the tunneling behavior of the device from direct tunneling to Fowler-Nordheim tunneling. An onset of tunneling dominated by Fowler-Nordheim emissions can be observed as a barrier thickness increases with higher annealing temperatures. Here, as shown in FIG. 6B, the low-field resistance changes by 6.5× from 375 °C to 425 °C but the transition voltage does not significantly change, signifying F-N emission as the dominant transport mechanism.

As to the oxidizing and selective etching of blocks 602 and 603, a self-limiting nature of the growth of the area-selective ALD deposited material 310 can result in structures that are physically separated by a small gap on the order of several nanometers in size to sub-nanometer scales. This allows for tolerances to physical and processing non-idealities like material roughness and error in pattern fidelity of the deposition template 120. In an exemplary case, the spacing of the reformed gap RG can be tailored by the oxidizing and selective etching of blocks 602 and 603 as shown in FIG. 7 resulting in larger spacing between features. This larger spacing can be employed in further CMOS processing (i.e., FEOL and/or BEOL).

As shown in FIG. 8, material of the deposition template 120 is deposited and patterned on the substrate 110 as described above. After the functionalization process to make the substrate 110 material ALD-inactive and the material of the deposition template 120 ALD-active, the area-selective ALD deposited material 310 is deposited area-selectively on the deposition template 120. The deposition and patterning of the deposition template 120 is formed such that the area-selective ALD deposited material 310 forms self-assembled wires 801. Due to the self-limiting nature of the area-selective ALD deposition, the self-assembled wires 801 do not fully short during the self-fabrication process, resulting in gaps 802 and thus higher resistance in the direction D1 perpendicular to the self-assembled wires 801 than in the parallel direction D2. If desired, the gaps 802 can be increased by controlled removal of the area-selective ALD deposited material 310. This will increase the spacing between the self-assembled wires 801 and thus increase the resistance between the self-assembled wires 801. The shape of the self-assembled wires 801 and the gaps 802 can be defined initially by the shape of the deposited and patterned deposition template 120.

In accordance with one or more additional embodiments, material can be deposited into the gaps 802 of FIG. 8. For example, in an exemplary case in which the area-selective ALD-deposited material 310 is electrically conductive and forms the wires 801 as discussed above, insulating material can be deposited into the gaps 802 to increase the resistance between the wires 801 without a need for widening the gaps 802. As another example, in an exemplary case in which the area-selective ALD-deposited material 310 is electrically non-conductive, conductive material can be deposited into the gaps 802 at any width of the gaps 802 to form wires of a given width. That is, metallic material could be deposited into the gaps 802 of the middle image of FIG. 8 to form wires of a first width and metallic material could be deposited into the gaps 802 of the right-most image of FIG. 8 to form wires of a second width. In any case, the shape of the wires can be defined initially by the shape of the deposited and patterned deposition template 120.

Various embodiments of the present disclosure are described herein with reference to the related drawings. Alternative embodiments can be devised without departing from the scope of this disclosure. Although various connections and positional relationships (e.g., over, below, adjacent, etc.) are set forth between elements in the following description and in the drawings, persons skilled in the art will recognize that many of the positional relationships described herein are orientation-independent when the described functionality is maintained even though the orientation is changed. These connections and/or positional relationships, unless specified otherwise, can be direct or indirect, and the present disclosure is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiments or designs. The terms “at least one” and “one or more” are understood to include any integer number greater than or equal to one, i.e. one, two, three, four, etc. The terms “a plurality” are understood to include any integer number greater than or equal to two, i.e. two, three, four, five, etc. The term “connection” can include an indirect “connection” and a direct “connection.”

References in the specification to “one embodiment,” “an embodiment,” “an example embodiment,” etc., indicate that the embodiment described can include a particular feature, structure, or characteristic, but every embodiment may or may not include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper,” “lower,” “right,” “left,” “vertical,” “horizontal,” “top,” “bottom,” and derivatives thereof shall relate to the described structures and methods, as oriented in the drawing figures. The terms “overlying,” “atop,” “on top,” “positioned on” or “positioned atop” mean that a first element, such as a first structure, is present on a second element, such as a second structure, wherein intervening elements such as an interface structure can be present between the first element and the second element. The term “direct contact” means that a first element, such as a first structure, and a second element, such as a second structure, are connected without any intermediary conducting, insulating or semiconductor layers at the interface of the two elements.

Spatially relative terms, e.g., “beneath,” “below,” “lower,” “above,” “upper,” and the like, can be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device can be otherwise oriented (rotated 90 degrees or at other orientations) and the spatially relative descriptors used herein interpreted accordingly.

The phrase “selective to,” such as, for example, “a first element selective to a second element,” means that the first element can be etched and the second element can act as an etch stop.

The terms “about,” “substantially,” “approximately,” and variations thereof, are intended to include the degree of error associated with measurement of the particular quantity based upon the equipment available at the time of filing the application. For example, “about” can include a range of ±8% or 5%, or 2% of a given value.

The term “conformal” (e.g., a conformal layer) means that the thickness of the layer is substantially the same on all surfaces, or that the thickness variation is less than 15% of the nominal thickness of the layer.

The terms “epitaxial growth and/or deposition” and “epitaxially formed and/or grown” mean the growth of a semiconductor material (crystalline material) on a deposition surface of another semiconductor material (crystalline material), in which the semiconductor material being grown (crystalline overlayer) has substantially the same crystalline characteristics as the semiconductor material of the deposition surface (seed material). In an epitaxial deposition process, the chemical reactants provided by the source gases can be controlled and the system parameters can be set so that the depositing atoms arrive at the deposition surface of the semiconductor substrate with sufficient energy to move about on the surface such that the depositing atoms orient themselves to the crystal arrangement of the atoms of the deposition surface. An epitaxially grown semiconductor material can have substantially the same crystalline characteristics as the deposition surface on which the epitaxially grown material is formed. For example, an epitaxially grown semiconductor material deposited on a {100} orientated crystalline surface can take on a {100} orientation. In some embodiments of the disclosure, epitaxial growth and/or deposition processes can be selective to forming on semiconductor surface, and cannot deposit material on exposed surfaces, such as silicon dioxide or silicon nitride surfaces.

As previously noted herein, for the sake of brevity, conventional techniques related to semiconductor device and integrated circuit (IC) fabrication may or may not be described in detail herein. By way of background, however, a more general description of the semiconductor device fabrication processes that can be utilized in implementing one or more embodiments of the present disclosure will now be provided. Although specific fabrication operations used in implementing one or more embodiments of the present disclosure can be individually known, the described combination of operations and/or resulting structures of the present disclosure are unique. Thus, the unique combination of the operations described in connection with the fabrication of a semiconductor device according to the present disclosure utilize a variety of individually known physical and chemical processes performed on a semiconductor (e.g., silicon) substrate, some of which are described in the immediately following paragraphs.

In general, the various processes used to form a micro-chip that will be packaged into an IC fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device. Semiconductor lithography is the formation of three-dimensional relief images or patterns on the semiconductor substrate for subsequent transfer of the pattern to the substrate. In semiconductor lithography, the patterns are formed by a light sensitive polymer called a photo-resist. To build the complex structures that make up a transistor and the many wires that connect the millions of transistors of a circuit, lithography and etch pattern transfer steps are repeated multiple times. Each pattern being printed on the wafer is aligned to the previously formed patterns and slowly the conductors, insulators and selectively doped regions are built up to form the final device.

The flowchart and block diagrams in the Figures illustrate possible implementations of fabrication and/or operation methods according to various embodiments of the present disclosure. Various functions/operations of the method are represented in the flow diagram by blocks. In some alternative implementations, the functions noted in the blocks can occur out of the order noted in the Figures. For example, two blocks shown in succession can, in fact, be executed substantially concurrently, or the blocks can sometimes be executed in the reverse order, depending upon the functionality involved.

The descriptions of the various embodiments of the present disclosure have been presented for purposes of illustration, but are not intended to be exhaustive or limited to the embodiments described. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments described herein.

What is claimed is:

1. A method of fabrication by self-assembly, the method comprising:
preparing a substrate;
patterning a deposition template onto the substrate to define a gap;
functionalizing substrate surfaces to be inactive to an atomic layer deposition (ALD) process and deposition template surfaces to be active to the ALD process;
area-selective ALD processing whereby deposited material does not nucleate and grow on the substrate surfaces and does nucleate and grow on the deposition template surfaces such that the gap is reformed as a reformed gap between deposition material surfaces; and
continuing the area-selective ALD processing whereby the reformed gap narrows without closing.

2. The method according to claim 1, wherein an initial size of the gap is about 20 nm to about 65 nm and a final size of the reformed gap is on a sub-nanometer scale.

3. The method according to claim 1, wherein at least one of the substrate comprises dielectric material, the deposition template comprises metallic material and the deposited material comprises a metallic nitride.

4. The method according to claim 1, wherein the functionalizing of the substrate surfaces comprises surface hydrogen removal and replacement with materials that prohibit ALD precursors from nucleating.

5. The method according to claim 1, wherein the substrate comprises silicon dioxide, the deposition template comprises aluminum, the deposited material comprises titanium nitride and the functionalizing of the substrate surfaces and the deposition template surfaces comprises exposure to nitrogen trifluoride plasma.

6. The method according to claim 1, further comprising annealing the deposition material surfaces at least at the reformed gap in air.

7. The method according to claim 1, further comprising:
oxidizing the deposition material surfaces at least at the reformed gap to form modified layers; and
selectively etching the modified layers to enlarge the reformed gap to a predefined width.

8. A method of fabrication by self-assembly, the method comprising:
preparing a substrate comprising substrate surfaces;
patterning a deposition template onto the substrate to comprise deposition template surfaces and to define a gap between opposing ones of the deposition template surfaces;
functionalizing the substrate surfaces to be inactive to an atomic layer deposition (ALD) process and the deposition template surfaces to be active to the ALD process;
area-selective ALD processing whereby deposited material does not nucleate and grow on the substrate surfaces and does nucleate and grow on the deposition template surfaces such that the gap is reformed as a reformed gap between opposing deposition material surfaces corresponding to the opposing ones of the deposition template surfaces; and
continuing the area-selective ALD processing whereby the reformed gap narrows without closing.

9. The method according to claim 8, wherein an initial size of the gap between the opposing ones of the deposition template surfaces is about 20 nm to about 65 nm and a final size of the reformed gap between the opposing deposition material surfaces is on a sub-nanometer scale.

10. The method according to claim 8, wherein at least one of the substrate comprises dielectric material, the deposition template comprises metallic material and the deposited material comprises a metallic nitride.

11. The method according to claim 8, wherein the functionalizing of the substrate surfaces comprises surface hydrogen removal and replacement with materials that prohibit ALD precursors from nucleating.

12. The method according to claim 8, wherein the substrate comprises silicon dioxide, the deposition template comprises aluminum, the deposited material comprises titanium nitride and the functionalizing of the substrate surfaces and the deposition template surfaces comprises exposure to nitrogen trifluoride plasma.

13. The method according to claim 8, further comprising annealing the deposition material surfaces at least at the reformed gap between the opposing deposition material surfaces in air.

14. The method according to claim 8, further comprising:
oxidizing the deposition material surfaces at least at the reformed gap between the opposing deposition material surfaces to form modified layers; and
selectively etching the modified layers to enlarge the reformed gap between the opposing deposition material surfaces to a predefined width.

15. A self-assembled device, comprising:
a substrate comprising substrate surfaces functionalized to be inactive to atomic layer deposition (ALD);
a deposition template patterned onto the substrate and comprising deposition template surfaces functionalized to be active to the ALD and defining a gap between opposing ones of the deposition template surfaces; and
area-selective ALD deposited material, which is nucleated and grown on the deposition template surfaces such that the gap is reformed as a reformed gap between opposing deposition material surfaces corresponding to the opposing ones of the deposition template surfaces.

16. The self-assembled device according to claim 15, wherein:
an initial size of the gap between the opposing ones of the deposition template surfaces is about 20 nm to about 65 nm and a final size of the reformed gap between the opposing deposition material surfaces is on a sub-nanometer scale, and
the opposing depositional material surfaces are rounded.

17. The self-assembled device according to claim 15, wherein a thickness of the deposition template is about 1 nm.

18. The self-assembled device according to claim 15, wherein at least one of the substrate comprises dielectric material, the deposition template comprises metallic material and the area-selective ALD deposited material comprises a metallic nitride.

19. The self-assembled device according to claim 15, wherein:
the substrate comprises silicon dioxide, the deposition template comprises aluminum, the deposited material comprises titanium nitride, and
the substrate surfaces and the deposition template surfaces are functionalized by exposure to nitrogen trifluoride plasma.

20. The self-assembled device according to claim 15, wherein a non-dimensional electrical resistance across the reformed gap between the opposing deposition material surfaces is about 1 or less than 1 for all temperatures, T, where 300K<T<at least 400.
